(19) United States
(12) Patent Application Publication
(10) Pub. No.: US 2024/0218768 A1
(43) Pub. Date: Jul. 4, 2024

(54) PRACTICAL STRATEGY TO FLOW THE NEW GENERATION OF SMART MULTILATERAL WELL COMPLETIONS

(71) Applicant: SAUDI ARABIAN OIL COMPANY, Dhahran (SA)

(72) Inventors: Wisam Shaker, Dhahran (SA); Majed Shammari, Dhahran (SA); Talal Sager, Dhahran (SA)

(73) Assignee: SAUDI ARABIAN OIL COMPANY, Dhahran (SA)

(21) Appl. No.: 18/148,862

(22) Filed: Dec. 30, 2022

(51) Int. Cl. E21B 43/14; E21B 43/12

(52) U.S. Cl. CPC E21B 43/14; E21B 43/12; E21B 2200/20

(57) ABSTRACT

The laterals of a smart multilateral completion are divided into a number of compartments for improved monitoring and controlling of unwanted fluid production. The productivity index (PI) of each compartment is determined by conducting downhole tests utilizing the downhole liquid metering, real-time pressure measurements, and the electrical inflow control valve (ICV). The PIs and other testing results are used to calibrate a multiphase single well simulation model to select the optimum ICV opening setting at each compartment. The calibrated simulation model is used in a fluid dynamic simulator (e.g., PIPESIM) to generate simulation results based on different ICV opening settings. The optimum ICV opening setting is selected based on the simulated well production delivering the target oil rate while satisfying the constraints of (i) the maximum allowable liquid production rate from each compartment and (ii) the maximum allowable reservoir pressure drawdown all the compartments combined.

### BACKGROUND

Multilateral well completion refers to the drilling and completion of multiple lateral boreholes within a single main borehole. Multilateral well completions provide alternatives to vertical, inclined, horizontal, and extended-reach wells. Intelligent completions, or smart completions, incorporate permanent downhole sensors and surface-controlled downhole flow control valves to monitor, evaluate, and actively manage production (or injection) in real time without any well interventions.

An inflow control valve (ICV) is an active component installed as part of a well completion to partially or completely choke fluid flow into a well. Inflow control valves can be installed along the reservoir section of the completion, with each device typically separated from the next via a packer. Each valve can be controlled from the surface to maintain flow conformance and, as the reservoir depletes, to stop unwanted fluids from entering the wellbore. A permanent downhole cable provides electric and hydraulic conduits to relay commands from the surface to each valve. The action of inflow control valves (ICVs) is key to improved management of flux imbalance and premature production delay of unwanted fluids from contributing laterals of the intelligent wells. Complexity in using ICVs includes determining all possible combinations of valve settings (e.g., 11 possible positions per valve on each lateral) and imposing specific wellbore pressure profiles in multilateral (e.g., dual or trilateral) well completions for continuous uninterrupted functioning of the smart wells.

### SUMMARY

In general, in one aspect, the invention relates to a method for performing a production operation of a well. The method includes disposing, within each of a plurality of compartments of a multilateral completion of the well, an integrated station comprising at least one inflow control valve (ICV) and at least one downhole sensor, generating, using each integrated station of the plurality of compartments, drawdown pressure and flowrate measurements by performing a pressure drawdown and build up test of each compartment, calibrating a simulation model of the multilateral completion, wherein a simulation result of the pressure drawdown and build up test using the calibrated simulation model matches the drawdown pressure and flowrate measurements of each compartment, performing, using the calibrated simulation model, a plurality of production simulations of the multilateral completion to generate a plurality of production simulation results, wherein each of the plurality of production simulations is based on one set of a plurality sets of ICV settings for the multilateral completion, selecting, by comparing the plurality of production simulation results to a maximum constraint, a set of target ICV settings from the plurality sets of ICV settings, wherein the set of target ICV settings comprises a target setting for each ICV of the multilateral completion, and performing, by at least applying the set of target ICV settings to the multilateral completion, the production operation of the well.

In general, in one aspect, the invention relates to a non-transitory computer readable medium storing instructions for performing a production operation of a well. The instructions, when executed by a computer processor, comprising functionality for performing a pressure drawdown and build up test of each of a plurality of compartments of a multilateral completion of the well, wherein the pressure drawdown and build up test is performed in cooperation with an integrated station disposed in each compartment, wherein the integrated station comprises at least one inflow control valve (ICV) and at least one downhole sensor, receiving, from the integrated station disposed in said each compartment, drawdown pressure and flowrate measurements of the pressure drawdown and build up test, calibrating a simulation model of the multilateral completion, wherein a simulation result of the pressure drawdown and build up test using the calibrated simulation model matches the drawdown pressure and flowrate measurements of each compartment, performing, using the calibrated simulation model, a plurality of production simulations of the multilateral completion to generate a plurality of production simulation results, wherein each of the plurality of production simulations is based on one set of a plurality sets of ICV settings for the multilateral completion, selecting, by comparing the plurality of production simulation results to a pre-determined criterion, a set of target ICV settings from the plurality sets of ICV settings, wherein the set of target ICV settings comprises a target setting for each ICV of the multilateral completion, and facilitating, by at least applying the set of target ICV settings to the multilateral completion, the production operation of the well.

In general, in one aspect, the invention relates to a well system for performing a production operation of a well. The well system includes a multilateral completion comprising a plurality of compartments, wherein an integrated station comprising at least one inflow control valve (ICV) and at least one downhole sensor is disposed in each compartment, and a data gathering and analysis system comprising functionalities for performing a pressure drawdown and build up test of each compartment, wherein the pressure drawdown and build up test is performed in cooperation with the integrated station disposed in each compartment, receiving, from the integrated station disposed in said each compartment, drawdown pressure and flowrate measurements of the pressure drawdown and build up test, calibrating a simulation model of the multilateral completion, wherein a simulation result of the pressure drawdown and build up test using the calibrated simulation model matches the drawdown pressure and flowrate measurements of each compartment, performing, using the calibrated simulation model, a plurality of production simulations of the multilateral completion to generate a plurality of production simulation results, wherein each of the plurality of production simulations is based on one set of a plurality sets of ICV settings for the multilateral completion, selecting, by comparing the plurality of production simulation results to a maximum constraint, a set of target ICV settings from the plurality sets of ICV settings, wherein the set of target ICV settings comprises a target setting for each ICV of the multilateral completion, and facilitating, by at least applying the set of target ICV settings to the multilateral completion, the production operation of the well.

Other aspects and advantages will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIGS. 1 and 2 show systems in accordance with one or more embodiments.

FIGS. 3A and 3B show flowcharts in accordance with one or more embodiments.

FIGS. 4A-4C and 5A-5B show examples in accordance with one or more embodiments.

FIG. 6 shows a computing system in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Embodiments of the invention provide a method and a system that automate the adjustments of ICV openings in a multilateral completion to provide a balanced inflow across production zones accessed by different laterals. The adjustments of ICV openings allow for adjusting the completion pressure differential to balance reservoir drawdown. As a result, unwanted fluids (e.g., gas and/or water) production are delayed and oil production is enhanced.

In one or more embodiments of the invention, the laterals of the multilateral completion are divided into a number of compartments for improved monitoring and controlling of unwanted fluid production. The productivity index (PI) of each compartment is determined by conducting downhole tests utilizing the downhole liquid metering, real-time pressure measurements, and the electrical inflow control valve (ICV). The PIs and other testing results are used to calibrate a multiphase single well simulation model to select the optimum ICV opening setting at each compartment. The calibrated simulation model is used in a fluid dynamic simulator (e.g., PIPESIM) to generate simulation results based on different ICV opening settings. The optimum ICV opening setting is selected based on the simulated well production delivering the target oil rate while satisfying the constraints of (i) the maximum allowable liquid production rate from each compartment and (ii) the maximum allowable reservoir pressure drawdown all the compartments combined.

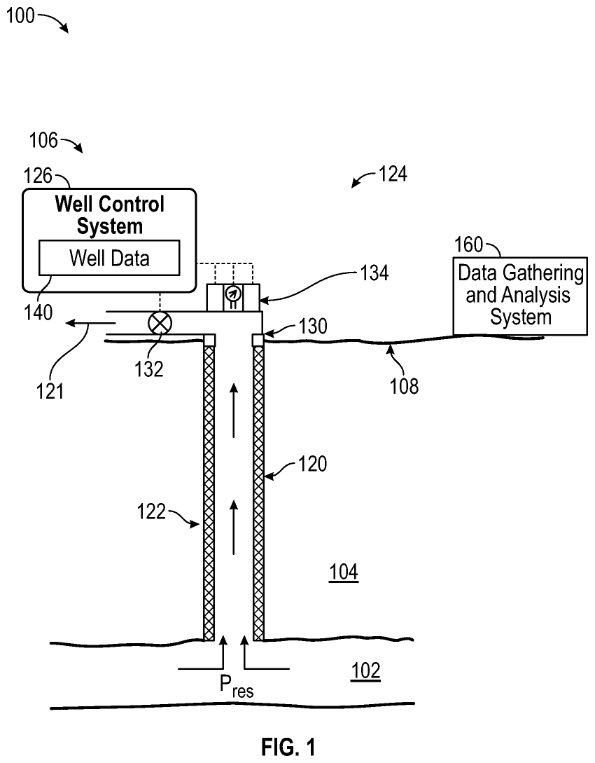

Turning to FIG. 1, FIG. 1 shows a schematic diagram in accordance with one or more embodiments. As shown in FIG. 1, FIG. 1 illustrates a well environment (100) that includes a hydrocarbon reservoir (“reservoir”) (102) located in a subsurface hydrocarbon-bearing formation (“formation”) (104) and a well system (106). The hydrocarbon-bearing formation (104) may include a porous or fractured rock formation that resides underground, beneath the earth's surface (“surface”) (108). In the case of the well system (106) being a hydrocarbon well, the reservoir (102) may include a portion of the hydrocarbon-bearing formation (104). The hydrocarbon-bearing formation (104) and the reservoir (102) may include different layers of rock having varying characteristics, such as varying degrees of permeability, porosity, capillary pressure, and resistivity. In the case of the well system (106) being operated as a production well, the well system (106) may facilitate the extraction of hydrocarbons (or “production”) from the reservoir (102).

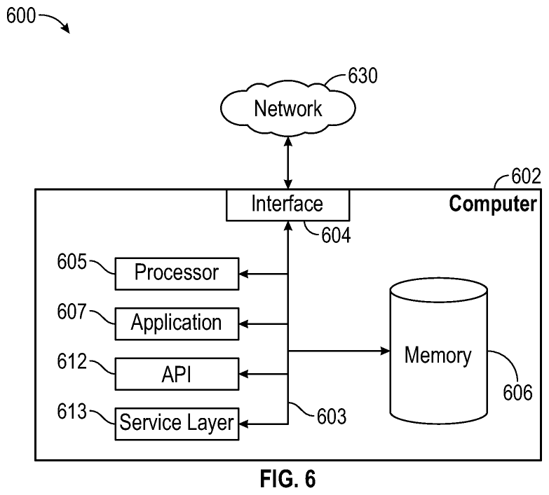

In some embodiments, the well system (106) includes a wellbore (120), a well sub-surface system (122), a well surface system (124), and a well control system (“control system”) (126). The control system (126) may control various operations of the well system (106), such as well production operations, well completion operations, well maintenance operations, and reservoir monitoring, assessment and development operations. In some embodiments, the control system (126) includes a computer system that is the same as or similar to that of computer system (600) described below in FIG. 6 and the accompanying description.

The wellbore (120) may include a bored hole that extends from the surface (108) into a target zone of the hydrocarbon-bearing formation (104), such as the reservoir (102). An upper end of the wellbore (120), terminating at or near the surface (108), may be referred to as the “up-hole” end of the wellbore (120), and a lower end of the wellbore, terminating in the hydrocarbon-bearing formation (104), may be referred to as the “down-hole” end of the wellbore (120). The wellbore (120) may facilitate the circulation of drilling fluids during drilling operations, the flow of hydrocarbon production (“production”) (121) (e.g., oil and gas) from the reservoir (102) to the surface (108) during production operations, the injection of substances (e.g., water) into the hydrocarbon-bearing formation (104) or the reservoir (102) during injection operations, or the communication of monitoring devices (e.g., logging tools) into the hydrocarbon-bearing formation (104) or the reservoir (102) during monitoring operations (e.g., during in situ logging operations).

In some embodiments, during operation of the well system (106), the control system (126) collects and records well data (140) for the well system (106). The well data (140) may include, for example, a record of wellhead and/or downhole measurements of pressure, temperature, flowrate over some or all of the life of the well (106), and water cut data. In some embodiments, the measurements are recorded in real-time, and are available for review or use within seconds, minutes or hours of the condition being sensed (e.g., the measurements are available within 1 hour of the condition being sensed). In such an embodiment, the well data (140) may be referred to as “real-time” well data (140). Real-time well data (140) may enable an operator of the well (106) to assess a relatively current state of the well system (106), and make real-time decisions regarding development of the well system (106) and the reservoir (102), such as on-demand adjustments in regulation of production flow from the well.

In some embodiments, the well sub-surface system (122) includes casing installed in the wellbore (120). For example, the wellbore (120) may have a cased portion and an uncased (or “open-hole”) portion. The cased portion may include a portion of the wellbore having casing (e.g., casing pipe and casing cement) disposed therein. The uncased portion may include a portion of the wellbore not having casing disposed therein. In some embodiments, the casing includes an annular casing that lines the wall of the wellbore (120) to define a central passage that provides a conduit for the transport of tools and substances through the wellbore (120). For example, the central passage may provide a conduit for lowering logging tools into the wellbore (120), a conduit for the flow of production (121) (e.g., oil and gas) from the reservoir (102) to the surface (108), or a conduit for the flow of injection substances (e.g., water) from the surface (108) into the hydrocarbon-bearing formation (104). In some embodiments, the well sub-surface system (122) includes production tubing installed in the wellbore (120). The production tubing may provide a conduit for the transport of tools and substances through the wellbore (120). The production tubing may, for example, be disposed inside casing. In such an embodiment, the production tubing may provide a conduit for some or all of the production (121) (e.g., oil and gas) passing through the wellbore (120) and the casing.

In some embodiments, the well surface system (124) includes a wellhead (130). The wellhead (130) may include a rigid structure installed at the “up-hole” end of the wellbore (120), at or near where the wellbore (120) terminates at the Earth's surface (108). The wellhead (130) may include structures for supporting (or “hanging”) casing and production tubing extending into the wellbore (120). Production (121) may flow through the wellhead (130), after exiting the wellbore (120) and the well sub-surface system (122), including, for example, the casing and the production tubing. In some embodiments, the well surface system (124) includes flow regulating devices that are operable to control the flow of substances into and out of the wellbore (120). For example, the well surface system (124) may include one or more production valves (132) that are operable to control the flow of production (134). For example, a production valve (132) may be fully opened to enable unrestricted flow of production (121) from the wellbore (120), the production valve (132) may be partially opened to partially restrict (or “throttle”) the flow of production (121) from the wellbore (120), and production valve (132) may be fully closed to fully restrict (or “block”) the flow of production (121) from the wellbore (120), and through the well surface system (124).

In some embodiments, the wellhead (130) includes a choke assembly. For example, the choke assembly may include hardware with functionality for opening and closing the fluid flow through pipes in the well system (106). Likewise, the choke assembly may include a pipe manifold that may lower the pressure of fluid traversing the wellhead. As such, the choke assembly may include set of high pressure valves and at least two chokes. These chokes may be fixed or adjustable or a mix of both. Redundancy may be provided so that if one choke has to be taken out of service, the flow can be directed through another choke. In some embodiments, pressure valves and chokes are communicatively coupled to the well control system (126). Accordingly, a well control system (126) may obtain wellhead data regarding the choke assembly as well as transmit one or more commands to components within the choke assembly in order to adjust one or more choke assembly parameters.

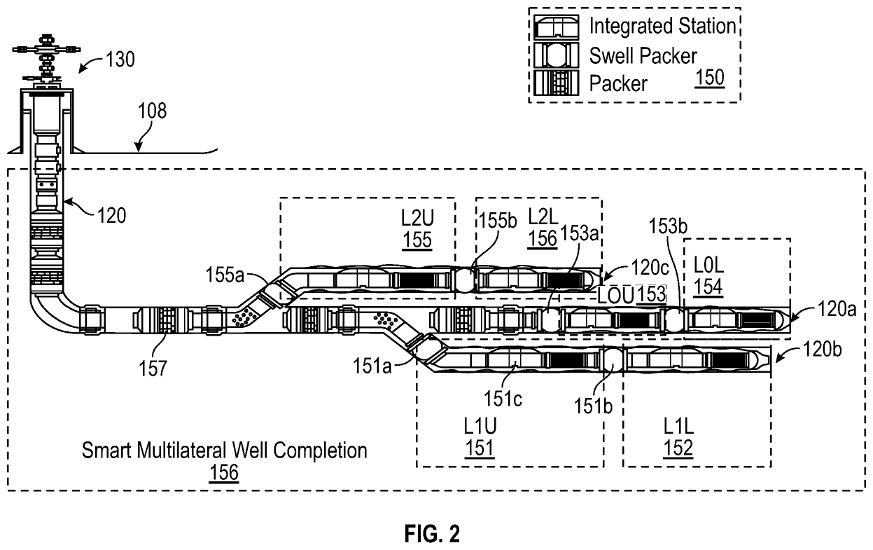

Keeping with FIG. 1, in some embodiments, the well surface system (124) includes a surface sensing system (134). The surface sensing system (134) may include sensors for sensing characteristics of substances, including production (121), passing through or otherwise located in the well surface system (124). The characteristics may include, for example, pressure, temperature and flowrate of production (121) flowing through the wellhead (130), or other conduits of the well surface system (124), after exiting the wellbore (120). Similarly, the well sub-surface system (122) includes various downhole sensors and control mechanisms that are described in reference to FIG. 2 below.

In some embodiments, the well system (106) includes a data gathering and analysis system (160). For example, the data gathering and analysis system (160) may include a hardware and/or software with functionality for performing a downhole test, gathering downhole test measurements, generating one or more reservoir and/or well models based on the gathered downhole test measurements, and/or performing one or more reservoir and/or well simulations using the generated models. In some embodiments, the data gathering and analysis system (160) provides the downhole test control settings and gathers the downhole test measurements via the well control system (126). While the data gathering and analysis system (160) is shown at a well site, embodiments are contemplated where data gathering and analysis system (160) is located away from well sites. In some embodiments, the data gathering and analysis system (160) may include a computer system that is similar to the computer system (600) described below with regard to FIG. 6 and the accompanying description.

Turning to FIG. 2, FIG. 2 shows a schematic diagram in accordance with one or more embodiments. Specifically, FIG. 2 illustrates an example well environment depicted in FIG. 1 above. The well environment includes a smart multilateral well completion (156), also referred to as a smart multilateral completion, of the wellbore (120). The smart multilateral well completion (156) includes a main branch (120a) (referred to as lateral #0) of the wellbore (120) (referred to as the mother bore) where the main branch is flanked by a lateral #1 (or branch (120b)) below and lateral #2 (or branch (120c)) above. For example, the lateral #0, lateral #1, and lateral #2 penetrate the formation at different depths to retrieve hydrocarbons from different geological layers. Each of the lateral #0, lateral #1, and lateral #2 is divided into a number of compartments utilizing the oil swell packers (i.e., based on oil-sensitive elastomers). A swell packer, or swellable packer, is an isolation device that relies on elastomers to expand and form an annular seal when immersed in certain wellbore fluids. The elastomers used in these packers are either oil-sensitive or water-sensitive. Oil-activated elastomers, which work on the principle of absorption and dissolution, are affected by fluid temperature as well as the concentration and specific gravity of hydrocarbons in a fluid.

As shown in FIG. 2 according to the legend (150), the compartments of the smart multilateral well completion (156) includes the upper compartment L1U (151) and lower compartment L1L (152) of the lateral #1 as divided by the swell packers (151a, 151b), the upper compartment L0U (153) and lower compartment L0L (154) of the main bore as divided by the swell packers (153a, 153b), and the upper compartment L2U (155) and lower compartment L2L (156) of the lateral #2 as divided by the swell packers (155a, 155b). In addition to the swell packers, the smart multilateral well completion (156) includes a number of additional packers (e.g., packer (157)).

Further as shown in FIG. 2 according to the legend (150), an integrated station (e.g., integrated station (151c)) is placed within each compartment for monitoring and controlling the production of unwanted fluids (e.g., gas and/or water). The unwanted fluids are fluids excluded from intended production (e.g., production (121)) of the well environment (100) as depicted in FIG. 1 above. The unwanted fluids production may occur when the maximum allowable liquid production rate and/or the maximum allowable reservoir pressure drawdown are exceeded in one or more compartments. For example, the unwanted fluids may cause production problems, such as the coning phenomenon when oil is produced. To perform the monitoring and controlling functions, each integrated station is equipped with pressure and temperature sensors, a water cut sensor, a fluid flow speed sensor (e.g., a venturi), and an electrical ICV. The real time sensor measurements of the integrated stations are transmitted from the smart lateral completions to the gas oil separation plant (GOSP) and the reservoir management department (RMD) office through a smart downhole-to-surface communication and control system. In one or more embodiments, the smart downhole-to-surface communication and control system includes the well control system (126) and the data gathering and analysis system (160) depicted in FIG. 1 above.

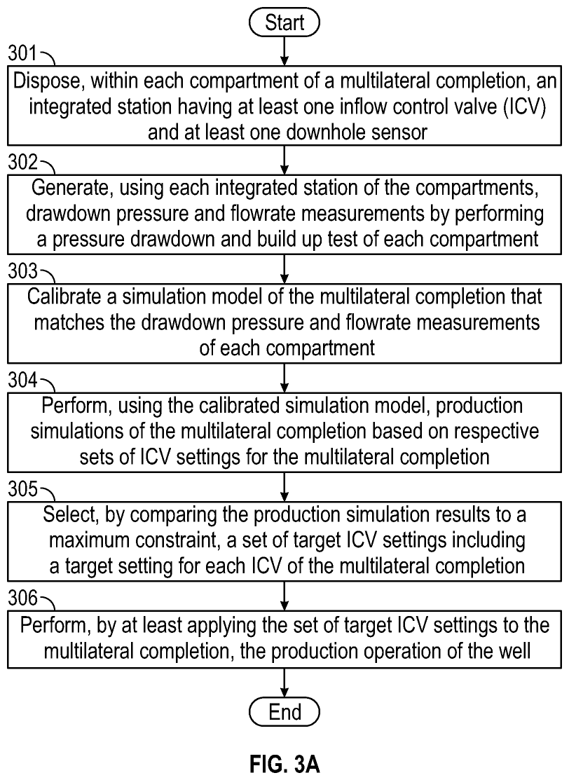

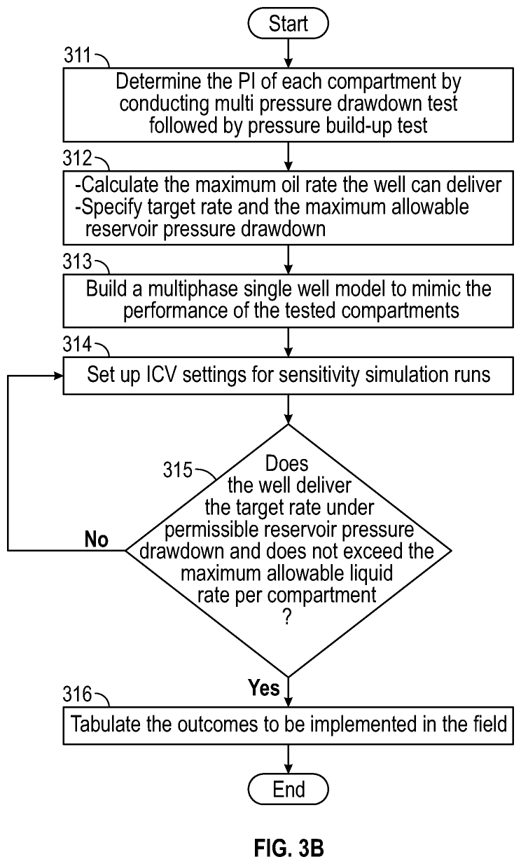

FIG. 3A shows a flowchart in accordance with one or more embodiments. Specifically, FIG. 3A describes a method for facilitating production of the smart multilateral well completions. One or more blocks in FIG. 3 may be performed using one or more components as described in FIGS. 1 and 2 above. While the various blocks in FIG. 3A are presented and described sequentially, one of ordinary skill in the art will appreciate that some or all of the blocks may be executed in different orders, may be combined or omitted, and some or all of the blocks may be executed in parallel. Furthermore, the blocks may be performed actively or passively.

Initially in Block 301, an integrated station is disposed within each compartment of a multilateral completion of the well. Each integrated station is provided with at least one inflow control valve (ICV) and at least one downhole sensor, such as a pressure sensor, flowrate sensor, etc.

In Block 302, drawdown pressure and flowrate measurements are generated using each integrated station of the compartments. These measurements are generated by performing a pressure drawdown and build up test of each compartment.

In Block 303, a simulation model of the multilateral completion is calibrated such that a simulation result of the pressure drawdown and build up test using the calibrated simulation model matches the drawdown pressure and flowrate measurements of each compartment.

In Block 304, a number of production simulations of the multilateral completion are performed, using the calibrated simulation model, to generate production simulation results. Each production simulation is based on one of multiple sets of ICV settings for the multilateral completion.

In Block 305, selecting, a set of target ICV settings is selected from multiple sets of ICV settings by comparing the production simulation results to a maximum constraint, such as the maximum allowable liquid production rate and the maximum allowable reservoir pressure drawdown. The selected set of target ICV settings includes a target setting for each ICV of the multilateral completion.

In Block 306, the production operation of the well is performed by at least applying the set of target ICV settings to the multilateral completion.

FIG. 3B shows an example flowchart/workflow for a smart multilateral completion based on the method flowchart depicted in FIG. 3A above. In particular, the workflow is used to model the liquid production flowrate for each compartment to match the target oil rate of the well, e.g., as defined according to the requirement of the RMD.

Initially in Block 311, the productivity index (PI) of each compartment of a smart multilateral well completion (e.g., the smart multilateral well completion (156) depicted in FIG. 2 above) is determined by conducting a multi-pressure drawdown test followed by a pressure build-up test. In one or more embodiments, the multi-pressure drawdown test and pressure build-up test are performed using the integrated stations of the smart multilateral well completion and under the control of the well control system (126) and data gathering and analysis system (160) depicted in FIG. 1 above. In this context, the well control system (126) and data gathering and analysis system (160) are collectively referred to as a smart downhole-to-surface communication and control system. Prior to the drawdown test of each compartment, the compartment under test is closed (i.e., shut-in) using an ICV in the integrated station of the compartment to allow the pressure to become equal throughout the surrounding reservoir/formation. In other words, the compartment under test is static/stable and a constant reservoir pressure is reached to begin the drawdown test. During the drawdown test, the ICV opens the compartment to flow at a constant producing rate while a series of bottom-hole pressure measurements is continuously recorded. For example, the flow rate at each compartment may be measured independent of each other using a Venturi to measure speed of fluid flow. After the compartment has been producing at constant rate for some time, the pressure build-up test is conducted by closing (i.e., shutting-in via the ICV) the compartment to allow the pressure to build up, and recording the down-hole pressure in the compartment as a function of time.

In one or more embodiments, the ICVs of the integrated stations are controlled by the smart downhole-to-surface communication and control system to open and close the compartments for the drawdown and pressure build-up test. Further, the pressure and flowrate measurements are obtained using sensors in the integrate stations and transmitted to the smart downhole-to-surface communication and control system. In one or more embodiments, the multi-pressure drawdown test is conducted with increasing choke sizes and under limited reservoir pressure.

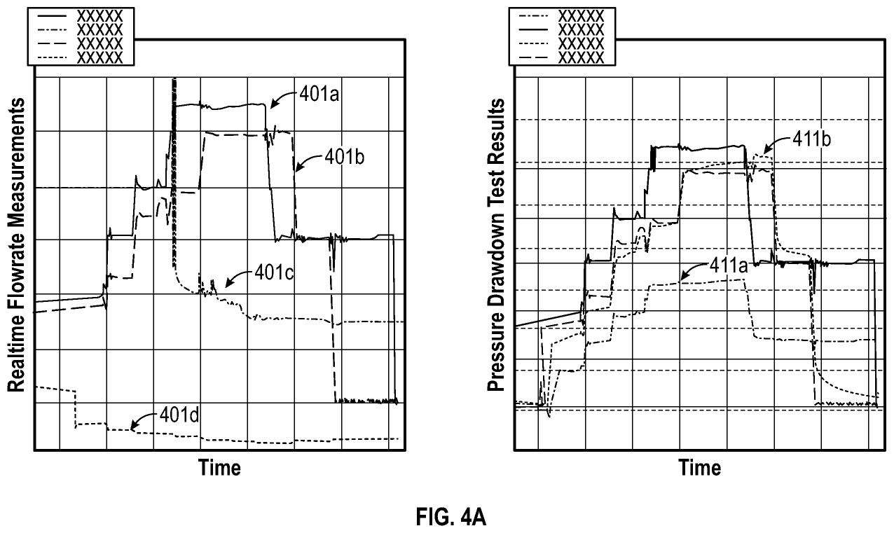

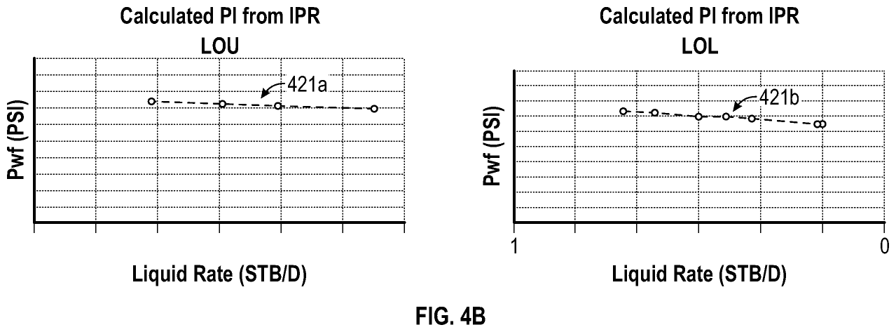

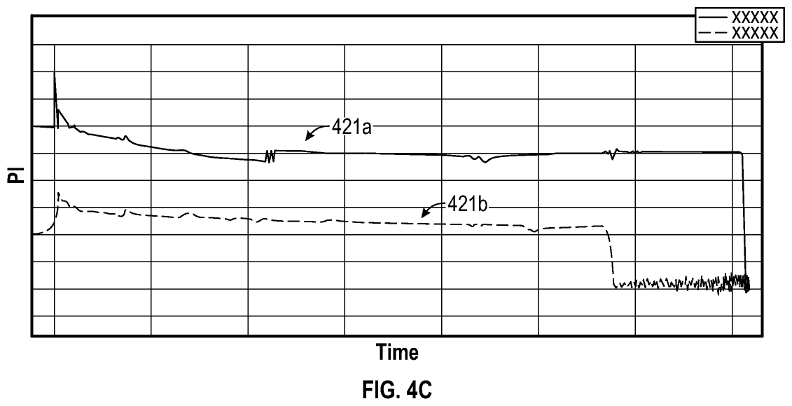

FIG. 4A illustrates real-time drawdown pressure and flowrate measurements of individual compartments in the smart multilateral well completion (156) depicted in FIG. 2 above. Specifically, the vertical axes correspond to the measurements with increasing magnitudes while the horizontal axes correspond to progression of time. In particular, measurements of the upper and lower compartments L0U and L0L are explicitly labeled as L0U flowrate (401a), L0L flowrate (401b), L0U watercut (401c), L0L watercut (401d), L0U drawdown pressure (411a), and L0L drawdown pressure (411b). As shown in FIG. 4A, the drawdown pressure and flowrate measurements start from low magnitudes at beginning of the test, rising to respective higher magnitudes before returning to lower magnitudes. The initial lower magnitudes, subsequent higher magnitudes, and the final lower magnitudes correspond to three stages of different ICV opening sizes resulting in different flow rates (i.e., more oil at each stage). In this contest, FIG. 2 is referred to as multi-rate test measurements.

The productivity index (PI) of the compartments L0U and L0L are calculated from inflow performance relationship (IPR) based on the measurements depicted in FIG. 4A. The IPR is an inflow pressure relationship between flowing bottom hole pressure and flow rate at different ICV openings, the slope of the IPR curve is the productivity index (PI). FIG. 4B illustrates the calculated L0U PI (421a) and L0L PI (421b) at different liquid rates. Specifically, the vertical axes correspond to the PI values while the horizontal axes correspond to the liquid rates. [The average flowrate at each stage in FIG. 4A is plotted against the corresponding flowing bottom hole pressure in to generate FIG. 4B]

FIG. 4C illustrates the calculated L0U PI (421a) and L0L PI (421b) after a period of production and stabilized at constant values to represent the steady state productivity index values Specifically, the vertical axes correspond to the PI values while the horizontal axes correspond to progression of time.

In one or more embodiments, the real-time drawdown pressure and flowrate measurements and derived calculation results shown in FIGS. 4A-4C are gathered and analyzed by the data gathering and analysis system (160) depicted in FIG. 1 above.

Returning to the flowchart of FIG. 3, in Block 312, the maximum flowrate that the well can deliver (referred to as the maximum oil production rate) is calculated by combining the maximum allowable liquid rate from each compartment. In particular, the maximum allowable liquid rate from each compartment is obtained as the difference of the bottom hole sensor readings between the static condition and flowing condition. For example, the maximum flowrate that the smart multilateral well completion (156) can deliver may be calculated by multiplying the maximum allowable liquid rate from each compartment (e.g., 1500 reservoir barrel (Rbbl)/day per compartment) by total number of compartments (i.e., 6), which equals 9000 Rbbl/day.

In one or more embodiments, a production target rate below the maximum oil production rate calculated above and the maximum allowable reservoir pressure drawdown for each compartment are specified by a user. For example, the target rate may be specified as 80% of the maximum oil production rate while the maximum allowable reservoir pressure drawdown is specified by a user, such as a RMD engineer.

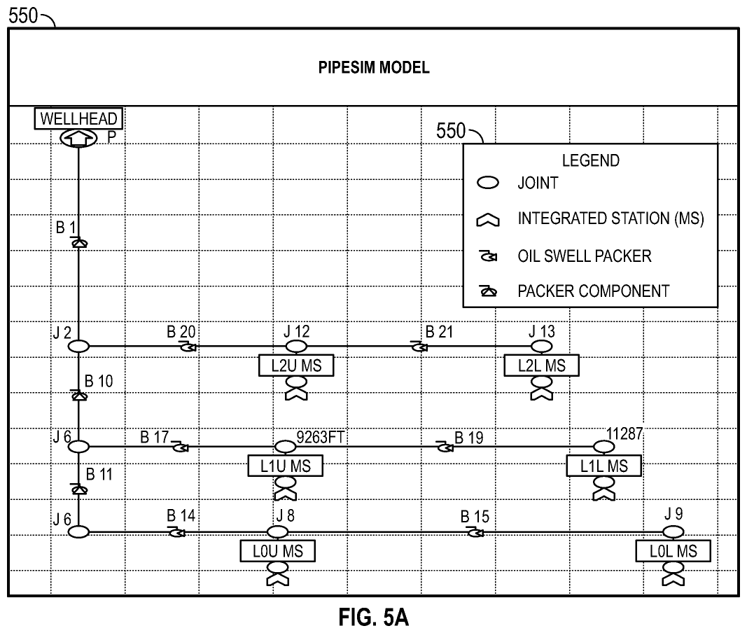

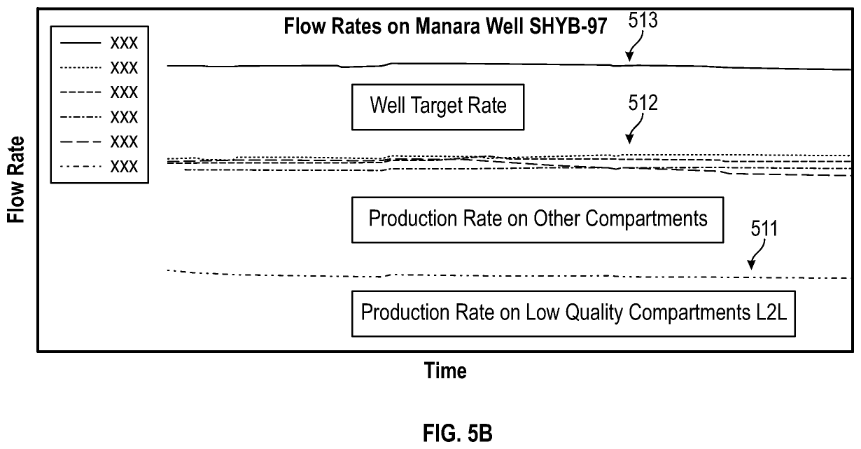

In Block 313, a smart multilateral well model is constructed or calibrated for the smart multilateral well completion. For the example, a smart tri-lateral well model with 2 compartments at each lateral is built to mimic the measured and calculated performance of the tested compartments of the smart multilateral well completion (156) depicted in FIGS. 4A-4C above. In one or more embodiments, the smart multilateral well model is a PIPESIM model (550) depicted in FIG. 5A. PIPESIM is a fluid dynamics simulator that includes standard completion model types for vertical, horizontal, and fractured wells, and allows for complex multilayered completions using a wide variety of reservoir inflow parameters and fluid descriptions. FIG. 5A illustrates, according to legend (550), the example PIPESIM smart tri-lateral well model (550) having three horizontal branches representing the three laterals #1, #2, and #3 of the smart multilateral well completion (156) for a single well. For example, J8, J9, J12 and J13 are reference numbers of the joints of the pipe network, L0U MS corresponds to the integrated station of the upper compartment in the lateral #0.

As shown in FIG. 5A, modeling parameters, e.g., opening position of the electrical ICV at each compartment, are adjusted in a calibration procedure such that PIPESIM model (550) mimic the measurements and calculated performance results of the smart multilateral well completion (156) depicted in FIGS. 4A-4C above.

In Block 314, ICV opening settings at each compartment of the smart multilateral well completion (e.g., the smart multilateral well completion (156)) are specified in the smart multilateral well model (e.g., PIPESIM model (550)). In particular, the settings specify the opening positions of the ICVs for simulating the production of the smart multilateral well completion (156) using the smart multilateral well model (e.g., PIPESIM model (550)). Block 314 may be iteratively performed corresponding to multiple simulation runs each with different ICV settings to evaluate sensitivity of the simulation results with respect to the ICV settings and to select optimum ICV settings. For example, initial ICV opening settings may be specified for the first simulation run and subsequently adjusted during each iteration according to a determination in Block 315 below. For example, the initial ICV settings may be specified as fully open ICVs and iteratively adjust the ICV position according to the outcomes of the PipeSim model, then follow up the drawdown pressure and measured flow rate after each adjustment until the target rate is achieved.

In Block 315, the simulation results of Block 314 are reviewed with respect to the production target rate and the maximum allowable reservoir pressure drawdown specified in Block 312. In particular, it is determined whether the well (i.e., the smart multilateral well completion (156)) produces at the production target rate within an tolerance, such as within 5% of the target rate, without exceeding the maximum allowable reservoir pressure drawdown. In other words, whether the reservoir pressure drawdown from each and every compartment combined does not exceed the maximum allowable reservoir pressure drawdown. If the determination is negative, i.e., the well does not produce at the production target rate and/or the maximum allowable reservoir pressure drawdown is exceeded, the method returns to Block 314 where the ICV settings are adjusted for another simulation run. If the determination is positive, i.e., the well does produce at the production target rate without exceeding the maximum allowable reservoir pressure drawdown, the method proceeds to Block 316.

In Block 316, the ICV opening settings and corresponding simulation results are tabulated. A set of example simulation results is shown in TABLE 1 where the surface choke is set at 42% and each row corresponds to one compartment of the smart multilateral well completion (156).

TABLE 1

| Column 1 | Column 2 | Column 3 | Column 4 | Column 5 | Column 6 |
|---|---|---|---|---|---|
| Compartment | {PI/Sum(PI)} (%) | q (%/ft) | {q/Q} (%) | Choke (%) | {DP/(sum DP)} (%) |
| L1L | 16.2 | | 18.4 | 86 | 17.3 |
| L1U | 17.2 | 0.8 | 18.6 | 57 | 10 |
| L2L | 5.4 | | 8 | 100 | 28 |
| L2U | 26 | 0.66 | 18.5 | 53 | 17.3 |
| L0L | 16.2 | | 18 | 86 | 17.2 |
| L0U | 19 | 0.8 | 18.6 | 55 | 10 |

PI: Productivity Index of the compartment,
Sum(PI): combined PIs from all compartments,
q: Liquid rate from the compartment,
Q: Well target rate,
Choke: ICV opening setting
DP: Pressure drawdown at compartment level,
Sum DP: combined DP of all compartments

In the simulated scenario shown in TABLE 1, the compartment L2L has lower liquid rate than the rest of compartments. As a result, the percentage fluid contribution (column 4) from each compartment is substantially the same except L2L, at less by 56% of other compartment, due to the maximum allowable reservoir pressure drawdown constraint.

To compensate for the lower liquid rate, the ICV opening (column 5) of the compartment L2L is fully open. Note that the influx percentage contribution per feet values (column 3) for #1, #2, and #0 laterals are comparable to each other.

The simulated scenario illustrates applying downhole flow control valves to control flow from individual laterals to reduce backpressure on other potential contributing laterals.

FIG. 5B illustrates the actual measured real-time flowrates of the compartments when the optimum ICV opening settings (referred to as target ICV settings) selected using the method described above are implemented in the physical well. As shown in FIG. 5B. the curve (511) corresponds to the physically measured flowrate of the compartment L2L, the group of comparable curves (512) correspond to the physically measured flowrates of the other compartments. The curve (513) corresponds to the physically measured combined flowrates of all compartments that achieves the well production target rate. In summary, the well production target rate is achieved using the modeled optimum ISV opening settings selected from the simulation results without iteratively adjusting the physical ICV opening settings in the actual lateral compartments in a trial-and-error procedure.

In one or more embodiments, the data calculations and analysis performed in Block 312 through Block 316, as well as the model generation/adjustments and real-time data analysis shown in FIGS. 5A-5B may be performed by the data gathering and analysis system (160) depicted in FIG. 1 above.

Embodiments may be implemented on a computer system. FIG. 6 is a block diagram of a computer system (600) used to provide computational functionalities associated with described algorithms, methods, functions, processes, flows, and procedures as described in the instant disclosure, according to an implementation. The illustrated computer system (600) is intended to encompass any computing device such as a high performance computing (HPC) device, a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer system (600) may include a computer (602) that includes an input device, such as a keypad, keyboard, touch screen, or other device that can accept user information, and an output device that conveys information associated with the operation of the computer (602), including digital data, visual, or audio information (or a combination of information), or a GUI.

The computer (602) can serve in a role as a client, network component, a server, a database or other persistency, or any other component (or a combination of roles) of a computer system for performing the subject matter described in the instant disclosure. The illustrated computer (602) is communicably coupled with a network (630). In some implementations, one or more components of the computer (602) may be configured to operate within environments, including cloud-computing-based, local, global, or other environment (or a combination of environments).

At a high level, the computer (602) is an electronic computing device operable to receive, transmit, process, store, or manage data and information associated with the described subject matter. According to some implementations, the computer (602) may also include or be communicably coupled with an application server, e-mail server, web server, caching server, streaming data server, business intelligence (BI) server, or other server (or a combination of servers).

The computer (602) can receive requests over network (630) from a client application (for example, executing on another computer (602)) and responding to the received requests by processing the said requests in an appropriate software application. In addition, requests may also be sent to the computer (602) from internal users (for example, from a command console or by other appropriate access method), external or third-parties, other automated applications, as well as any other appropriate entities, individuals, systems, or computers.

Each of the components of the computer (602) can communicate using a system bus (603). In some implementations, any or all of the components of the computer (602), both hardware or software (or a combination of hardware and software), may interface with each other or the interface (604) (or a combination of both) over the system bus (603) using an application programming interface (API) (612) or a service layer (613) (or a combination of the API (612) and service layer (613). The API (612) may include specifications for routines, data structures, and object classes. The API (612) may be either computer-language independent or dependent and refer to a complete interface, a single function, or even a set of APIs. The service layer (613) provides software services to the computer (602) or other components (whether or not illustrated) that are communicably coupled to the computer (602). The functionality of the computer (602) may be accessible for all service consumers using this service layer. Software services, such as those provided by the service layer (613), provide reusable, defined business functionalities through a defined interface. For example, the interface may be software written in JAVA, C++, or other suitable language providing data in extensible markup language (XML) format or other suitable format. While illustrated as an integrated component of the computer (602), alternative implementations may illustrate the API (612) or the service layer (613) as stand-alone components in relation to other components of the computer (602) or other components (whether or not illustrated) that are communicably coupled to the computer (602). Moreover, any or all parts of the API (612) or the service layer (613) may be implemented as child or sub-modules of another software module, enterprise application, or hardware module without departing from the scope of this disclosure.

The computer (602) includes an interface (604). Although illustrated as a single interface (604) in FIG. 6, two or more interfaces (604) may be used according to particular needs, desires, or particular implementations of the computer (602). The interface (604) is used by the computer (602) for communicating with other systems in a distributed environment that are connected to the network (630). Generally, the interface (604) includes logic encoded in software or hardware (or a combination of software and hardware) and operable to communicate with the network (630). More specifically, the interface (604) may include software supporting one or more communication protocols associated with communications such that the network (630) or interface's hardware is operable to communicate physical signals within and outside of the illustrated computer (602).

The computer (602) includes at least one computer processor (605). Although illustrated as a single computer processor (605) in FIG. 6, two or more processors may be used according to particular needs, desires, or particular implementations of the computer (602). Generally, the computer processor (605) executes instructions and manipulates data to perform the operations of the computer (602) and any algorithms, methods, functions, processes, flows, and procedures as described in the instant disclosure.

The computer (602) also includes a memory (606) that holds data for the computer (602) or other components (or a combination of both) that can be connected to the network (630). For example, memory (606) can be a database storing data consistent with this disclosure. Although illustrated as a single memory (606) in FIG. 6, two or more memories may be used according to particular needs, desires, or particular implementations of the computer (602) and the described functionality. While memory (606) is illustrated as an integral component of the computer (602), in alternative implementations, memory (606) can be external to the computer (602).

The application (607) is an algorithmic software engine providing functionality according to particular needs, desires, or particular implementations of the computer (602), particularly with respect to functionality described in this disclosure. For example, application (607) can serve as one or more components, modules, applications, etc. Further, although illustrated as a single application (607), the application (607) may be implemented as multiple applications (607) on the computer (602). In addition, although illustrated as integral to the computer (602), in alternative implementations, the application (607) can be external to the computer (602).

There may be any number of computers (602) associated with, or external to, a computer system containing computer (602), each computer (602) communicating over network (630). Further, the term “client,” “user,” and other appropriate terminology may be used interchangeably as appropriate without departing from the scope of this disclosure. Moreover, this disclosure contemplates that many users may use one computer (602), or that one user may use multiple computers (602).

In some embodiments, the computer (602) is implemented as part of a cloud computing system. For example, a cloud computing system may include one or more remote servers along with various other cloud components, such as cloud storage units and edge servers. In particular, a cloud computing system may perform one or more computing operations without direct active management by a user device or local computer system. As such, a cloud computing system may have different functions distributed over multiple locations from a central server, which may be performed using one or more Internet connections. More specifically, cloud computing system may operate according to one or more service models, such as infrastructure as a service (IaaS), platform as a service (PaaS), software as a service (SaaS), mobile “backend” as a service (MBaaS), serverless computing, artificial intelligence (AI) as a service (AIaaS), and/or function as a service (FaaS).

Embodiments provide the following advantages: (i) as a quick and efficient tool for the production engineer to achieve target rate at the well level with optimum fluid rate from each compartment to replace the conventional trial and error procedure, (ii) achieving the inflow balancing among laterals and compartments to avoid the early breakthroughs of unwanted gas and/or water leading to higher oil recovery.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims. In the claims, any means-plus-function clauses are intended to cover the structures described herein as performing the recited function(s) and equivalents of those structures. Similarly, any step-plus-function clauses in the claims are intended to cover the acts described here as performing the recited function(s) and equivalents of those acts. It is the express intention of the applicant not to invoke 35 U.S.C. § 112(f) for any limitations of any of the claims herein, except for those in which the claim expressly uses the words “means for” or “step for” together with an associated function.

What is claimed is:

1. A method for performing a production operation of a well, the method comprising:
disposing, within each of a plurality of compartments of a multilateral completion of the well, an integrated station comprising at least one inflow control valve (ICV) and at least one downhole sensor;
generating, using each integrated station of the plurality of compartments, drawdown pressure and flowrate measurements by performing a pressure drawdown and build up test of each compartment;
calibrating a simulation model of the multilateral completion, wherein a simulation result of the pressure drawdown and build up test using the calibrated simulation model matches the drawdown pressure and flowrate measurements of each compartment;
performing, using the calibrated simulation model, a plurality of production simulations of the multilateral completion to generate a plurality of production simulation results, wherein each of the plurality of production simulations is based on one set of a plurality sets of ICV settings for the multilateral completion;
selecting, by comparing the plurality of production simulation results to a maximum constraint, a set of target ICV settings from the plurality sets of ICV settings, wherein the set of target ICV settings comprises a target setting for each ICV of the multilateral completion; and
performing, by at least applying the set of target ICV settings to the multilateral completion, the production operation of the well.

2. The method according to claim 1, further comprising:
disposing a plurality of swell packers in a plurality of laterals of the multilateral completion of the well to form the plurality of compartments.

3. The method according to claim 2,
wherein the maximum constraint comprises a maximum allowable liquid production rate of the plurality of compartments and a maximum allowable reservoir pressure drawdown.

4. The method according to claim 3,
wherein the set of target ICV settings is selected to balance flowrate contributions from the plurality of laterals of the multilateral completion.

5. The method according to claim 4,
wherein balancing flowrate contributions from the plurality of laterals of the multilateral completion is based on the maximum allowable liquid production rate of the plurality of compartments and the maximum allowable reservoir pressure drawdown to prevent early breakthrough of unwanted gas and/or water.

6. The method according to claim 1, wherein performing the pressure drawdown and build up test of each compartment comprises:
receiving, by the integrated station of said each compartment and from a smart downhole-to-surface communication and control system, a test setting of the at least one ICV of said each compartment;
controlling, by the integrated station using the test setting, the at least one ICV during the pressure drawdown and build up test of said each compartment; and
transmitting, by the integrated station of said each compartment and to the smart downhole-to-surface communication and control system, the drawdown pressure and flowrate measurements of said each compartment.

7. The method according to claim 1,
wherein the at least one ICV comprises an electrical ICV.

8. A non-transitory computer readable medium storing instructions for performing a production operation of a well, the instructions, when executed by a computer processor, comprising functionality for:
performing a pressure drawdown and build up test of each of a plurality of compartments of a multilateral completion of the well, wherein the pressure drawdown and build up test is performed in cooperation with an integrated station disposed in each compartment, wherein the integrated station comprises at least one inflow control valve (ICV) and at least one downhole sensor;
receiving, from the integrated station disposed in said each compartment, drawdown pressure and flowrate measurements of the pressure drawdown and build up test;
calibrating a simulation model of the multilateral completion, wherein a simulation result of the pressure drawdown and build up test using the calibrated simulation model matches the drawdown pressure and flowrate measurements of each compartment;
performing, using the calibrated simulation model, a plurality of production simulations of the multilateral completion to generate a plurality of production simulation results, wherein each of the plurality of production simulations is based on one set of a plurality sets of ICV settings for the multilateral completion;
selecting, by comparing the plurality of production simulation results to a pre-determined criterion, a set of target ICV settings from the plurality sets of ICV settings, wherein the set of target ICV settings comprises a target setting for each ICV of the multilateral completion; and
facilitating, by at least applying the set of target ICV settings to the multilateral completion, the production operation of the well.

9. The non-transitory computer readable medium according to claim 8,
wherein a plurality of swell packers are disposed in a plurality of laterals of the multilateral completion of the well to form the plurality of compartments.

10. The non-transitory computer readable medium according to claim 9,
wherein the maximum constraint comprises a maximum allowable liquid production rate of the plurality of compartments and a maximum allowable reservoir pressure drawdown.

11. The non-transitory computer readable medium according to claim 10,
wherein the set of target ICV settings is selected to balance flowrate contributions from the plurality of laterals of the multilateral completion.

12. The non-transitory computer readable medium according to claim 11,
wherein balancing flowrate contributions from the plurality of laterals of the multilateral completion is based on the maximum allowable liquid production rate of the plurality of compartments and the maximum allowable reservoir pressure drawdown to prevent early breakthrough of unwanted gas and/or water.

13. The non-transitory computer readable medium according to claim 8, wherein performing the pressure drawdown and build up test of each compartment comprises:
receiving, by the integrated station of said each compartment and from a smart downhole-to-surface communication and control system, a test setting of the at least one ICV of said each compartment;
controlling, by the integrated station using the test setting, the at least one ICV during the pressure drawdown and build up test of said each compartment; and
transmitting, by the integrated station of said each compartment and to the smart downhole-to-surface communication and control system, the drawdown pressure and flowrate measurements of said each compartment.

14. The non-transitory computer readable medium according to claim 8,
wherein the at least one ICV comprises an electrical ICV.

15. A well system for performing a production operation of a well, the well system comprising:
a multilateral completion comprising a plurality of compartments, wherein an integrated station comprising at least one inflow control valve (ICV) and at least one downhole sensor is disposed in each compartment; and
a data gathering and analysis system comprising functionalities for:
performing a pressure drawdown and build up test of each compartment, wherein the pressure drawdown and build up test is performed in cooperation with the integrated station disposed in each compartment;
receiving, from the integrated station disposed in said each compartment, drawdown pressure and flowrate measurements of the pressure drawdown and build up test;
calibrating a simulation model of the multilateral completion, wherein a simulation result of the pressure drawdown and build up test using the calibrated simulation model matches the drawdown pressure and flowrate measurements of each compartment;
performing, using the calibrated simulation model, a plurality of production simulations of the multilateral completion to generate a plurality of production simulation results, wherein each of the plurality of production simulations is based on one set of a plurality sets of ICV settings for the multilateral completion;
selecting, by comparing the plurality of production simulation results to a maximum constraint, a set of target ICV settings from the plurality sets of ICV settings, wherein the set of target ICV settings comprises a target setting for each ICV of the multilateral completion; and
facilitating, by at least applying the set of target ICV settings to the multilateral completion, the production operation of the well.

16. The well system according to claim 15,
wherein a plurality of swell packers are disposed in a plurality of laterals of the multilateral completion of the well to form the plurality of compartments.

17. The well system according to claim 16,
wherein the maximum constraint comprises a maximum allowable liquid production rate of the plurality of compartments and a maximum allowable reservoir pressure drawdown.

18. The well system according to claim 17,
wherein the set of target ICV settings is selected to balance flowrate contributions from the plurality of laterals of the multilateral completion.

19. The well system according to claim 18,
wherein balancing flowrate contributions from the plurality of laterals of the multilateral completion is based on the maximum allowable liquid production rate of the plurality of compartments and the maximum allowable reservoir pressure drawdown to prevent early breakthrough of unwanted gas and/or water.

20. The well system according to claim 15, wherein performing the pressure drawdown and build up test of each compartment comprises:
receiving, by the integrated station of said each compartment and from a smart downhole-to-surface communication and control system, a test setting of the at least one ICV of said each compartment;
controlling, by the integrated station using the test setting, the at least one ICV during the pressure drawdown and build up test of said each compartment; and
transmitting, by the integrated station of said each compartment and to the smart downhole-to-surface communication and control system, the drawdown pressure and flowrate measurements of said each compartment.
